(19) United States
(12) Patent Application Publication
(10) Pub. No.: US 2026/0123159 A1
(43) Pub. Date: Apr. 30, 2026

(54) LIGHT EMITTING DIODE PACKAGE AND APPARATUS INCLUDING THE SAME

(71) Applicant: Seoul Semiconductor Co., Ltd., Ansan-si (KR)

(72) Inventor: Jang Weon LEE, Ansan-si (KR)

(21) Appl. No.: 19/370,937

(22) Filed: Oct. 28, 2025

Related U.S. Application Data
(60) Provisional application No. 63/713,560, filed on Oct. 29, 2024.

(51) Int. Cl. H10H 29/855; F21S 41/141; F21S 41/25; F21S 41/32; F21W 102/155; F21Y 115/10; H10H 29/24; H10H 29/85

(52) U.S. Cl. CPC H10H 29/855; F21S 41/141; F21S 41/25; F21S 41/32; H10H 29/24; H10H 29/8506; F21W 2102/155; F21Y 2115/10

(57) ABSTRACT

A light emitting apparatus including at least one light emitting device, a light transmissive layer disposed on the light emitting device, and a cover layer disposed on the light transmissive layer and partially covering an upper surface of the light transmissive layer.

### CROSS REFERENCE TO RELATED APPLICATION

This application claims priority from and the benefit of U.S. Provisional Application No. 63/713,560, filed on Oct. 29, 2024, which is hereby incorporated by reference for all purposes as if fully set forth herein.

### BACKGROUND

### Field

Embodiments of the invention relate generally to a light emitting diode package and a light emitting apparatus including the same.

### Discussion of the Background

A light emitting diode (LED) is a light-emitting device that emits light when an electric current is applied. In recent years, light emitting diodes have been widely used in various fields, such as display devices, vehicle lamps, and general lighting. Light emitting diodes have various advantages such as long lifespan, low power consumption, and fast response. With such advantages, light emitting diodes are rapidly replacing existing light sources. For example, a display device adopting light emitting diodes can be obtained by forming separate red, green, and blue LED of red (R), green (G), and blue (B) light emitting diodes (LEDs) structures grown individually on a final substrate.

The above information disclosed in this Background section is only for understanding of the background of the inventive concepts, and, therefore, it may contain information that does not constitute prior art.

### SUMMARY

Embodiments of the present invention may provide a light emitting diode package and a light emitting apparatus including the same having a simple structure and can form a beam pattern of a desired shape with a compact size.

Embodiments of the present invention may provide a light emitting diode package and a light emitting apparatus including the same that reduces chromatic aberration.

Embodiments of the present invention may provide a light emitting diode package and a light emitting apparatus including the same that improves the sharpness of a projection image.

Embodiments of the present invention may provide a light emitting diode package and a light emitting apparatus including the same that improves reliability.

Additional features of the inventive concepts will be set forth in the description which follows, and in part will be apparent from the description, or may be learned by practice of the inventive concepts.

In accordance with one aspect of the present invention, a light emitting apparatus includes a light emitting device, a light transmissive layer disposed on the light emitting device, and a cover layer disposed on the light transmissive layer and partially covering an upper surface of the light transmissive layer.

In one embodiment, the cover layer may have a lower light transmittance than the light transmissive layer.

In one embodiment, a boundary between a cover region covered by the cover layer and an exposure region excluding the cover region on the upper surface of the light transmissive layer may include a stepped structure.

In one embodiment, the light emitting apparatus may further include a low light transmissive layer surrounding the light transmissive layer.

In one embodiment, the low light transmissive layer may have a lower light transmittance than the light transmissive layer.

In one embodiment, the cover layer may have a lower light transmittance than the low light transmissive layer.

In one embodiment, the boundary may include a first boundary line parallel to a first direction, a second boundary line connected to the first boundary line and forming a first angle with the first boundary line, and a third boundary line connected to the second boundary line and parallel to the first direction.

In one embodiment, the second boundary line may be a slope zone having an inclination with respect to the first and third boundary lines.

In one embodiment, the cover region may have a smaller area than the exposure region.

In one embodiment, a beam pattern of light emitted through the exposure region may include a high irradiance region corresponding to the first boundary line and having a relatively high irradiance, a variable irradiance region corresponding to the second boundary line and having a variable irradiance, and a low irradiance region corresponding to the third boundary line and having a relatively low irradiance.

In one embodiment, the beam pattern of the light emitted through the exposure region may have an asymmetrical light emission pattern.

In one embodiment, the variable irradiance region and the high irradiance region may have a light emission pattern extending above an upper boundary of the low irradiance region in a second direction perpendicular to the first direction.

In one embodiment, the light emitting apparatus may further include a lens module on which light emitted from the light emitting diode package is incident.

In accordance with another aspect of the present invention, a light emitting apparatus may include a light emitting diode package, a reflector on which light emitted from the light emitting diode package is incident, and a lens controlling an optical path of light reflected from the reflector, the light emitting diode package including: a light emitting device; a light transmissive layer disposed on the light emitting device; and a cover layer disposed on the light transmissive layer and partially covering an upper surface of the light transmissive layer, wherein the cover layer has a lower light transmittance than the light transmissive layer, and a boundary between a cover region covered by the cover layer and an exposure region excluding the cover region on the upper surface of the light transmissive layer includes a stepped structure.

In one embodiment, the cover layer has a thickness greater than 1/5 of a thickness of the light transmissive layer.

In one embodiment, the light emitting apparatus may further include a lens module on which light emitted from the light emitting diode package is incident.

In one embodiment, the lens module may include a plurality of refractive surfaces sequentially disposed in a traveling direction of the emitted light.

In one embodiment, the lens module may include a first lens, a second lens, and a third lens sequentially disposed in the traveling direction of the emitted light.

In one embodiment, the first lens may include a first refractive surface on which light is incident and a second refractive surface through which light exits; the second lens may include a third refractive surface on which light is incident and a fourth refractive surface through which the light exits; and the third lens may include a fifth refractive surface on which light is incident and a sixth refractive surface through which light exits.

In one embodiment, the first refractive surface may be a planar surface, the second refractive surface, the third refractive surface, the fifth refractive surface, and the sixth refractive surface may be convex surfaces, and the fourth refractive surface may be a concave surface.

In one embodiment, the first refractive surface may be a planar surface and the second refractive surface may be a spherical surface.

In one embodiment, the first lens may have a lower coefficient of thermal expansion than the second lens and the third lens.

In one embodiment, the fifth refractive surface may be located within at least one region of a depression formed by the fourth refractive surface.

In one embodiment, the first lens, the second lens, and the third lens may have different indices of refraction.

In one embodiment, the light emitting apparatus may further include an aperture having an opening disposed on a light emission side of the lens module, the opening being consistent with an optical axis of the lens module.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a conceptual diagram of a beam pattern projected by an automotive headlamp emitting a beam toward the front.

FIG. 2 is a view illustrating one example of the beam pattern of FIG. 1.

FIG. 3 is a perspective view of a light emitting diode package according to one embodiment of the present invention.

FIG. 4A and FIG. 4B are schematic perspective views of the light emitting diode package shown in FIG. 3.

FIG. 5 is a cross-sectional view of the light emitting diode package shown in FIG. 3.

FIG. 6 is a view illustrating a modified example of the light emitting diode package shown in FIG. 5.

FIG. 7 is a view illustrating a beam pattern of light emitted from an upper surface of the light emitting diode package shown in FIG. 3.

FIG. 8 is a top view of a light emitting diode package according to another embodiment of the present invention.

FIG. 9 is a view illustrating a light emitting apparatus according to a first embodiment of the present invention.

FIG. 10 is a view illustrating a light emitting apparatus according to a second embodiment of the present invention.

FIG. 11 is a partial plan view of the light emitting apparatus shown in FIG. 10.

FIG. 12 is a diagram illustrating the irradiance of each region in the beam pattern of FIG. 7.

FIG. 13 is a conceptual diagram illustrating an automotive headlamp including a plurality of light emitting apparatuses.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

An automotive headlamp refers to a light emitting module for illuminating the front of a vehicle 10 and may be disposed on a front side of the vehicle 10. The automotive headlamp may include a low beam headlamp emitting a low beam or a high beam headlamp emitting a high beam.

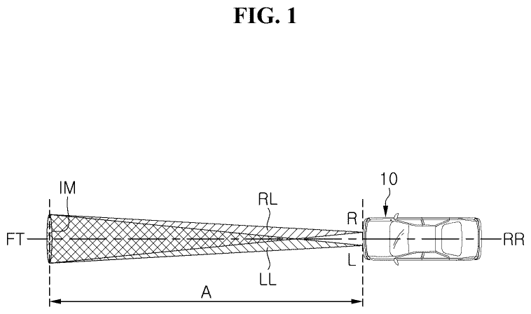

Referring to FIG. 1, when a forward direction of the vehicle 10 is denoted by FT and a reverse direction thereof is denoted by RR, the automotive headlamp may be disposed on the front side of the vehicle 10 facing the forward direction FT. A right beam RL emitted from the right side R of the automotive headlamp and a left beam LL emitted from the left side L thereof may overlap each other at a predetermined forward distance A to be projected in a single beam pattern IM. The forward distance A may vary depending on design. For example, the forward distance A may be spaced 25 meters from the automotive headlamp in the forward direction FT.

For example, the beams RL, LL emitted from the headlamps may be low beams. The low beam may refer to a low beam emitting headlamp, such as a headlamp that emits light downwardly. In another example, the beams RL, LL emitted from the headlamps may be high beams. The high beam may refer to a high beam emitting headlamp, such as a headlamp that emits light forwardly to illuminate the road ahead more brightly.

High beams are used temporarily under special conditions, whereas low beams are used for extended periods, usually at night when ambient irradiance is low, which can cause dazzling for a driver of an oncoming vehicle (driving in an oncoming lane), depending on the beam pattern. If the intensity of irradiated light is reduced to prevent glare to oncoming vehicles, the front of the vehicle 10 becomes difficult to see from a driver's side. Thus, it is important to form a beam pattern IM capable of reducing glare experienced by the driver of the oncoming vehicle while increasing visibility of the driver of the vehicle 10.

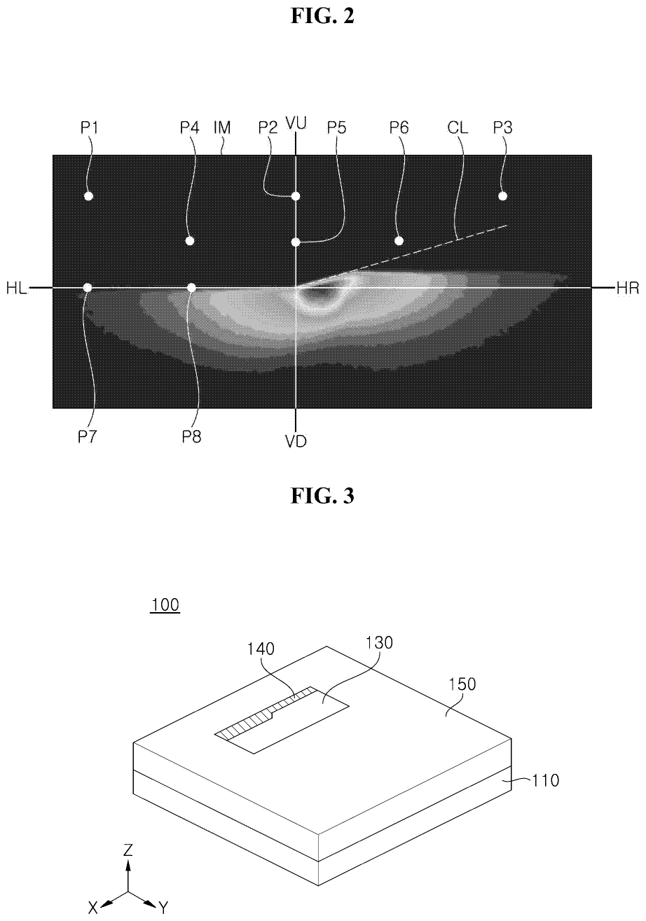

For example, FIG. 2 shows an exemplary low beam IM, which is oriented downward of a horizontal line HL-HR and may form a cut-off line CL at an angle with respect to the horizontal line HL-HR. FIG. 2 illustrates an example of a beam pattern IM of a low beam for a left-hand drive vehicle 10, in which the cut-off line CL is formed on the right side with respect to a vertical line VU-VD. Alternatively, the cut-off line CL may be formed on the left side with respect to the vertical line VU-VD for a right-hand drive vehicle 10. The cut-off line CL may be designed to appear in the projected beam pattern IM when the low beam of the headlamp is turned on.

In the beam pattern IM, an upper side of the cut-off line CL is configured as a dark area to reduce glare to oncoming vehicles, and a lower side of the cut-off line CL is configured as a light area to provide the driver with a good view of a front road and signs. For example, the cut-off line CL may be formed upwards at an angle of 15° with respect to the horizontal line HL-HR, without being limited thereto. However, it should be noted that the angle defined between the cut-off line CL and the horizontal line HL-HR may have various values depending on design.

If the cut-off line CL does not appear clearly and is distorted, light can be scattered above the cut-off line CL, thereby causing serious glare to a driver of an oncoming vehicle and risks a significant car accident. Thus, it is important to design and control the cut-off line precisely.

The cut-off line CL may be designed to satisfy a preset luminous intensity criterion (maximum luminous intensity or minimum luminous intensity) at a plurality of preset points P1 to P8. For example, referring to FIG. 2, points P1, P2, P3 are located above the horizontal line HL-HR and the sum of luminous intensities at points P1, P2, P3 may satisfy at least 190 cd. At points P4, P5, P6, the sum of luminous intensities may be at least 375 cd. Point P7 located on the horizontal line HL-HR is a region close to an oncoming vehicle and the luminous intensity at point P7 may be at least 65 cd. At point P8 on the horizontal line HL-HR, the luminous intensity may be at least 125 cd.

As a light emitting apparatus, a light emitting diode package 100 according to an embodiment of the present invention has a simple structure and can easily form a beam pattern IM that can secure driver visibility and can prevent glare to oncoming vehicles, as shown in FIG. 2.

FIG. 3 is a perspective view of a light emitting diode package according to one embodiment of the present invention.

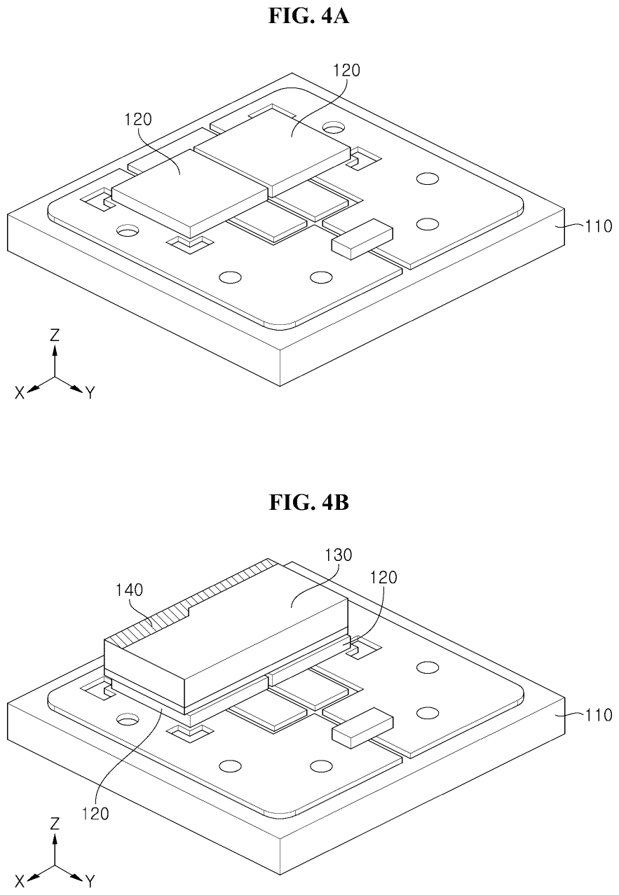

Referring to FIG. 3, the light emitting diode package 100 according to an embodiment may include a light emitting device 120 (see FIGS. 4A and 4B), a light transmissive layer 130 disposed on the light emitting device 120, and a cover layer 140 disposed on the light transmissive layer 130 and partially covering an upper surface of the light transmissive layer 130.

The light emitting device 120 may be a light emitting diode that emits light. For example, the light emitting device 120 may include a light emitting diode chip disposed on one surface of a wiring substrate 110 and generating light, and may have various configurations. The wiring substrate 110 may include an insulating layer and wiring for electrical connection with the light emitting device 120, and may include circuitry for power supply and driving the light emitting device 120.

The wiring substrate 110 may be formed in a multilayer structure and may be formed in various thicknesses, as needed.

The light emitting device 120 may be mounted on an upper surface of the wiring substrate 110 in various ways including wiring, bonding, soldering, or others.

The light emitting device 120 may include a semiconductor layer formed on a growth substrate. The growth substrate may be selected from any substrates on which a nitride semiconductor can be grown, and may include, for example, a heterogeneous substrate, such as a sapphire substrate, a silicon substrate, a silicon carbide substrate, or a spinel substrate, and may also include a homogeneous substrate, such as a gallium nitride substrate, an aluminum nitride substrate, or others.

The light emitting device 120 may include a first conductivity type semiconductor layer, an active layer, and a second conductivity type semiconductor layer.

The first conductivity type semiconductor layer may be a semiconductor layer grown on one surface of the growth substrate, and a buffer layer may be further formed between the first conductivity type semiconductor layer and the growth substrate. The buffer layer may include a nitride semiconductor, such as GaN, and may be grown using MOCVD. The buffer layer can improve crystallinity of the semiconductor layers grown on the growth substrate in a subsequent process, and can also act as a seed layer for growth of nitride semiconductor layers on a heterogeneous substrate.

The first conductivity type semiconductor layer may include a nitride semiconductor, such as (Al, Ga, In)N, and may be formed by growth on the growth substrate using a method, such as MOCVD, MBE, HVPE, or others. Furthermore, the first conductivity type semiconductor layer may be doped with at least one n-type dopant, such as Si, C, Ge, Sn, Te, Pb, and or/others. However, the inventive concepts are not limited thereto, and in some embodiments, the first conductivity type semiconductor layer may be doped with a p-type dopant to have opposite conductivity.

The active layer is a light emitting layer formed on the first conductivity type semiconductor layer and may have a multi-quantum well (MQW) structure. The active layer may include a nitride semiconductor, such as (Al, Ga, In)N, and may be grown on the first conductivity type semiconductor layer using a technique, such as MOCVD, MBE, HVPE, or others. Further, the active layer may include a quantum well (QW) structure including at least two barrier layers and at least one well layer, and may further include a multi-quantum well (MQW) structure including a plurality of barrier layers and a plurality of well layers.

The wavelength of light emitted from the active layer may be adjusted by controlling the composition ratio of the nitride semiconductor layer in the well layer. For example, the well layer may include a nitride semiconductor containing indium (In).

The well layer is located between the barrier layers and has a narrower energy bandgap than the barrier layer. The well layer may include or be formed of InₓGa₍₁₋ₓ₎N (0 [symbol] x [symbol] 1), in which the composition ratio (x) of In may be controlled according to the wavelength of light emitted from the active layer.

The barrier layers and the well layers are alternately stacked one above another. In an embodiment, the barrier layers and the well layers may be alternately stacked at least twice. A barrier layer and a well layer adjacent thereto may constitute a pair.

The second conductivity type semiconductor layer may be a semiconductor layer formed on the active layer.

The second conductivity type semiconductor layer may include a nitride semiconductor, such as (Al, Ga, In)N, and may be grown by a technique, such as MOCVD, MBE, HVPE, or others.

The second conductivity type semiconductor layer may be doped to have a conductivity type opposite to the conductivity type of the first conductivity type semiconductor layer. For example, the second conductivity type semiconductor layer may be doped with p-type dopants, such as Mg.

The second conductivity type semiconductor layer may have a monolayer structure having a composition, such as p-GaN, and may further include an AlGaN layer therein, without being limited thereto.

The light emitting device 120 may include an insulating layer covering the first conductivity type semiconductor layer and the second conductivity type semiconductor layer and defining openings in which two electrode pads are disposed. The two electrode pads may be electrically connected to the first conductivity type semiconductor layer and the second conductivity type semiconductor layer, respectively, through the openings in the insulating layer. However, it should be understood that the structure of the light emitting device 120 is not limited thereto and may be implemented in various structures.

The light emitting device 120 in other embodiments may be modified to be implemented in various structures including a flip-chip structure, a vertical structure, a lateral structure, or others. In some embodiments, the growth substrate may be omitted depending on the shape of the light emitting device 120. It should be understood that that the plurality of light emitting diodes 21 may be vertically stacked to form a single light emitting unit.

The light emitting device 120 may be provided singularly or in plural. When the light emitting device 120 is provided in plural, at least two light emitting devices 120 may be arranged side by side in a first direction. In this structure, the two light emitting devices 120 arranged side by side may share a side surface. Accordingly, light may be overlapped in a region of a light emitting region formed by the light emitting devices 120. With this structure, it is possible to make it easier to design a beam angle.

FIG. 4A illustrates an example in which two light emitting devices 120 are arranged side by side on the wiring substrate 110. In some embodiments, a single light emitting device 120 may be disposed on the wiring substrate 110, or three or more light emitting devices 120 may be disposed thereon in various configurations. In this structure, the light emitting region formed by at least one light emitting device 120 or the plurality of light emitting devices 120 may have a shape in which a length in one direction is longer than a length in another direction perpendicular thereto.

The light emitting region formed by at least one light emitting device 120 or the plurality of light emitting devices 120 may have a generally rectangular shape. For example, in FIG. 4A, the light emitting region formed by two light emitting devices 120 may be arranged to form a rectangular shape in which a length in the x-axis direction is longer than a length in the y-axis direction. The length in the x-axis direction may be two to five times the length in the y-axis direction. With this structure, the headlamp of the vehicle 10 can illuminate a wide horizontal plane of a road when projecting the beam pattern IM, whereby driver visibility and safety can be improved.

Accordingly, for light emitted from the light emitting region, a beam angle measured in one direction may be wider than a beam angle measured in a direction perpendicular to the one direction. For example, in FIG. 4A, a beam angle measured in the X-axis direction may be wider than a beam angle measured in the Y-axis direction.

The light transmissive layer 130 is disposed on the light emitting device 120, such that light emitted from the light emitting device 120 passes therethrough, and may have various configurations. One surface of the light transmissive layer 130 may be a light emission surface through which the transmitted light is emitted.

Referring to FIG. 4B, the light transmissive layer 130 is disposed on one surface of the light emitting device 120, and when a plurality of light emitting devices 120 is disposed on the wiring substrate 110, at least some light emitting devices among the plurality of light emitting devices 120 may share the light transmissive layer 130.

The plurality of light emitting devices 120 may share at least one light transmissive layer 130. This structure can reduce process difficulty. In another example, the light emitting diode package 100 may include a plurality of light transmissive layers 130. The plurality of light transmissive layers 130 may be spaced apart from each other or may be disposed adjacent to each other. This structure can increase contrast of the beam pattern IM.

In addition, the light transmissive layer 130 may have a monolayer structure or a multilayer structure stacked in the vertical direction.

The light transmissive layer 130 may be disposed on one surface of the light emitting device 120. The light emitting device 120 may be a first light transmitting region through which light generated by the active layer passes. In addition, the light transmissive layer 130 may be a second light transmitting region through which light having passed through the first light transmitting region passes. The first light transmitting region may have a larger area than the active layer with reference to a plane parallel to the active layer. This structure allows light emitted from the active layer to be emitted over a larger area through the first light transmitting region. Further, at least a region of the second light transmitting region may have a larger area than the first light transmitting region with reference to a plane parallel to the first light transmitting region. This structure allows light from the first light transmitting region to be emitted over a larger area through the second light transmitting region. The area of the second light transmitting region may be 10% to 40% of the area of the first light transmitting region. If the area of the second light transmitting region is less than 10% of that of the first light transmitting region, light loss can increase; and if the area of the second light transmitting region is larger than 40% of that of the first light transmitting region, the second light transmitting region can extend to a less efficient region, which can increase production costs.

The first light transmitting region and the second light transmitting region may have high light transmittance. For example, the first light transmitting region and the second light transmitting region may have a light transmittance of 70% or more. This structure can reduce light loss.

For example, the light transmissive layer 130 may be formed of various light transmissive materials, such as glass, silicon, ceramic, epoxy, or others.

The light transmissive layer 130 may further include a wavelength conversion material that converts the wavelength of light emitted from the light emitting device 120. The light transmissive layer 130 may include a fluorescent film containing a wavelength conversion material. The fluorescent film may include PIG (Phosphor in Glass), PIS (Phosphor in Silicone), PIC (Phosphor in Ceramic), or others, which include a wavelength conversion material together with a light transmitting material. Light produced through excitation of the wavelength conversion material may have a longer wavelength than light emitted from the light emitting device 120. A peak wavelength of the light produced through excitation of the wavelength conversion material may be 90 nm to 120 nm longer than a peak wavelength of the light emitted from the light emitting device 120. This structure can provide a broader color gamut. Furthermore, a peak of an excitation wavelength may be similar to a peak of a visual sensitivity curve. A difference between the peak of the excitation wavelength and the peak of the visual sensitivity curve may be about 50 nm.

The peak of the excitation wavelength may be in the range of 520 nm to 560 nm. This structure can improve driver visibility through improvement in visual sensitivity. The light transmissive layer 130 may include at least one of a wavelength conversion material or a light diffuser.

The wavelength conversion material may include quantum dots or phosphors capable of emitting light with a peak wavelength in the green or light wavelength band. For example, the phosphors may include at least one type selected from among LuAG series, YAG series, beta-SiAlON series, nitride series, silicate series, halophosphate series, and acid nitride series.

Furthermore, the wavelength conversion material may be quantum dots or phosphors capable of emitting light with a peak wavelength in the red wavelength band. For example, the phosphors may include at least one type selected from among nitride series, such as CASN, CASON, and SCASN, silicate series, sulfide series, and fluoride series. It should be understood that the wavelength conversion material for the light transmissive layer 130 is not limited to the aforementioned types and may include various types of materials capable of converting wavelengths of light in other embodiments. The diffuser may include fillers, such as SiO₂, TiO₂, BaSO₄, or others.

At least a region of an upper surface of the light transmissive layer 130 may be a light emission region through which light is emitted to the outside. This structure allows the beam angle to be adjusted by a refractive effect upon light emission through the light emission region.

The cover layer 140 may be disposed in an upper region on the light transmissive layer 130 to cover at least one region of the upper surface of the light transmissive layer 130. The cover layer 140 may have a lower light transmittance than the light transmissive layer 130. More particularly, the cover layer 140 may be a low transmittance region having low light transmittance. The cover layer 140 may have a light transmittance of 50% or less. In an embodiment, the cover layer 140 has a light transmittance of 10% or less. The cover layer 140 has low light transmittance and the shape of the light beam pattern IM can be easily adjusted by adjusting the shape of the cover layer 140.

The cover layer 140 may be disposed in at least one region of a side edge on the upper surface of the light transmissive layer 130. For example, as shown in FIG. 4B, three side edges of the cover layer 140 may overlap with side edges on the upper surface of the light transmissive layer 130. Furthermore, the cover layer 140 may be disposed in regions of the side edges on the upper surface of the light transmissive layer 130. The cover layer 140 can improve resolution of the beam pattern IM by reducing light leakage in the side edge regions of the light transmissive layer 130. The area of the cover layer 140 may be equal to or larger than 5% and less than 20% of the area of the light transmissive layer 130. If the area of the cover layer 140 is larger than 20% of the area of the light transmissive layer 130, there can be a problem of deterioration in luminous efficacy. If the area of the cover layer 140 is smaller than 5% of the area of the light transmissive layer 130, there can be a problem of reduced resolution of the beam pattern IM.

Light generated by the light emitting device 120 may be partially blocked by the cover layer 140 and may be emitted to the outside through an exposure region of the light transmissive layer 130 that is not covered by the cover layer 140. The exposure region of the light transmissive layer 130 may have higher irradiance than the region covered by the cover layer 140. This can be measured through a light emission pattern of light emitted from the light emitting diode package 100. For example, a light emission pattern by the region in which the cover layer 140 is disposed may have an irradiance of less than 70 lux, and a light emission pattern by the exposure region of the light transmissive layer 130 in which the cover layer 140 is not disposed may have an irradiance of 140 lux or more. As another example, the minimum irradiance of the light emission pattern by the region in which the cover layer 140 is disposed may be less than 50% of the maximum irradiance of the light emission pattern by the exposure region of the light transmissive layer 130. The cover layer 140 has low light transmittance and the shape of the beam pattern IM of emitted light can be easily adjusted by adjusting the shape of the cover layer 140.

The cover layer 140 may be formed of various materials with low light transmittance. For example, the cover layer 140 may be formed of a metallic material, such as Al, Gu, Ag, Ti, Ni, or others, or an organic material comprising a low transmittance material. The low transmittance material may include white or black fillers. As another example, the cover layer 140 may be formed by carbonization using a laser, inkjet printing, sputtering, or others, or may be bonded to a region of the light transmissive layer 130. This structure makes it easy to design the shape of the beam pattern IM by adjusting the light emission path.

Furthermore, a region of the cover layer 140 may further include a light absorbing material. The cover layer 140 may have a light reflectivity of less than 40%. This structure can improve resolution of the beam pattern IM. The cover layer 140 may have roughness on one surface thereof to reduce light reflectivity. With this structure, the light emitting diode package can reduce light interference by providing various traveling paths of light.

In another embodiment, the cover layer 140 may include a light reflective material. For example, the light reflective material may be disposed on one surface of the cover layer 140. In this structure, light can be reflected from one surface of the cover layer 140 that has high light reflectivity, thereby reducing thermal damage by reducing light-induced degradation. The light reflective material may include at least one selected from among metallic materials, such as Al, Ag, and Au, and oxides, such as TiO₂, BaSO₄, and silica.

The cover layer 140 may be formed parallel to one surface of the light transmissive layer 130. The cover layer 140 may have a constant thickness in one region. With this structure, the light emitting apparatus can maintain a constant light shielding rate, whereby the beam pattern IM can maintain a constant shape.

The cover layer 140 may have a thinner thickness in an outer peripheral region away from the center of the light emitting region than in a central region of the cover layer 140. Even without increasing the thickness of the cover layer 140 in the outer peripheral region of the cover layer 140 in which the intensity of light is relatively low, it is possible to form the beam pattern IM while reducing design difficulty.

The cover layer 140 may have a thinner thickness than the light transmissive layer 130. The thickness of the cover layer 140 may refer to a thickness in a direction parallel to a stacking direction (Z-axis direction) of semiconductor layers in the light emitting device 120. Since the light transmissive layer 130 has a greater thickness than the cover layer 140, it is possible to secure a sufficient light path in the light transmissive layer 130. Furthermore, the cover layer 140 and the light transmissive layer 130 may be formed in a certain thickness ratio. For example, the thickness of the cover layer 140 may be less than or equal to ½ of the thickness of the light transmissive layer 130. Furthermore, the thickness of the cover layer 140 may be greater than or equal to ⅕ of the thickness of the light transmissive layer 130. If the thickness of the cover layer 140 is greater than ½ of the thickness of the light transmissive layer 130, a shadow area can be generated by the cover layer 140. If the thickness of the cover layer 140 is thinner than ⅕ of the thickness of the light transmissive layer 130, the light blocking effect can decrease, thereby reducing resolution of the beam pattern IM. With this structure, the light emitting diode package can reduce shadowing caused by the thickness of the cover layer 140, thereby improving resolution of the beam pattern IM.

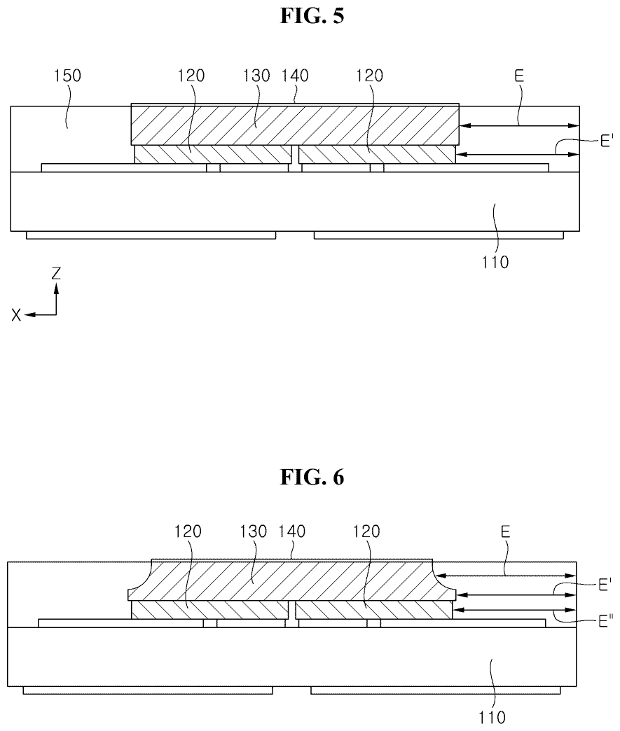

The light emitting diode package 100 may further include a low light transmissive layer 150 (see FIG. 5) that surrounds the light transmissive layer 130.

The low light transmissive layer 150 is disposed on the wiring substrate 110 to surround the light transmissive layer 130 and a side surface of the light emitting device 120, and may be formed in various configurations. The low light transmissive layer 150 may cover the remaining region of the light transmissive layer 130 excluding the upper surface thereof and may function as a protective layer that protects the light emitting device 120.

The low light transmissive layer 150 may have a lower light transmittance than the light transmissive layer 130. More particularly, the low light transmissive layer 150 may be a low transmission region with low light transmittance. The low light transmissive layer 150 may have a transmittance of less than 20%. With this structure, the light emitting diode package can improve resolution of the beam pattern IM by blocking light emitted through the side surfaces of the light emitting device 120 and the light transmissive layer 130.

The low light transmissive layer 150 may be disposed on a side surface of the plurality of light emitting devices 120 facing each other. With this structure, the light emitting apparatus can reduce chromatic aberration caused by light interference of each of the plurality of light emitting devices 120.

For example, the low light transmissive layer 150 may be formed of an organic material including a low transmittance material. The low light transmissive layer 150 may include silicone, PMMA (poly(methyl methacrylate)), PPA (polyphthalamide), epoxy, or others. Furthermore, the low light transmitting material may include white or black fillers. With this structure, it is possible to adjust light transmittance of the low light transmissive layer 150.

The low light transmissive layer 150 may further include a light absorbing material. The light absorbing material can reduce light interference through absorption of light outside a required region. The low light transmissive layer 150 may include fillers, such as TiO₂, BaSO₄, silica, and pigments, to reduce light transmittance.

The cover layer 140 may have a lower light transmittance than the low light transmissive layer 150. When measuring the light emission pattern from the front of the light emitting diode package 100, the relative intensity of light in the region of the cover layer 140 may be lower than the relative intensity of light in the region of the low light transmissive layer 150. For example, when measuring the light emission pattern using a CCD camera or sCMOS sensor, a count value in the region of the low transmissive layer 150 may be higher than the count value in the region of the cover layer 140.

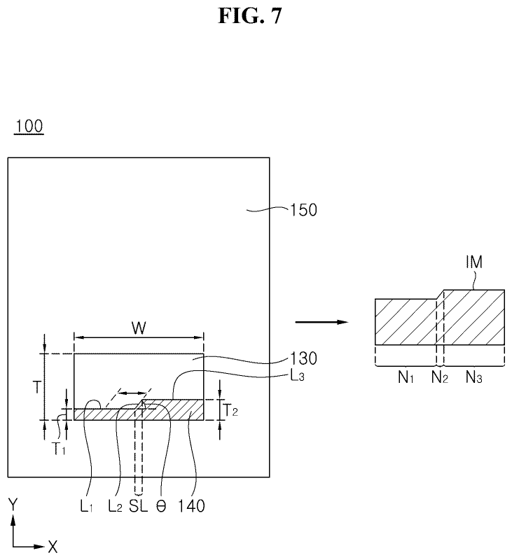

FIG. 5 and FIG. 6 are cross-sectional views of the light emitting diode package 100 according to embodiments. FIG. 7 is a top view of the light emitting diode package 100, in which a region of the upper surface of the light transmissive layer 130 forms a cover region by the cover layer 140 and a remaining region of the upper surface of the light transmissive layer 130 forms an exposure region exposed to the outside. Although FIG. 7 shows an example in which the light emitting diode package 100 is formed in a generally hexahedral shape and an upper surface of the light emitting diode package 100 is formed in a quadrangular shape, it should be understood that the inventive concepts are not limited thereto.

Since the cover region is covered by the cover layer 140 which is a low transmittance region, the cover region may be a region that blocks light from being emitted therethrough, and the exposure region may be a light emission region from which light is emitted.

The upper surface of the light transmissive layer 130 may be formed in various shapes in plan view. Although FIG. 4A and FIG. 4B show that the light transmissive layer 130 is formed in a quadrangular shape in plan view, it should be understood that the inventive concepts are not limited to a particular shape of the light transmissive layer 130. Accordingly, the cover region may also be formed in various shapes in plan view. The shape of the cover region may vary depending on the shape of the cover layer 140. The shape of the exposure region may also vary depending on the shape of the cover layer 140.

Furthermore, in a region where the second light transmitting region (light transmissive layer 130) adjoins the first light transmitting region (light emitting device 120), the second light transmitting region may have a larger area than the first light transmitting region with reference to a plane parallel to the active layer. This structure can improve light extraction efficiency at a junction between the first light transmitting region and the second light transmitting region by enlarging an area of a light receiving region.

Referring to FIG. 5, in one embodiment, the light exit surface of the light transmissive layer 130 may have a similar area to a light incident surface thereof. An area difference between the light exit surface and the light incident surface may be less than 10%. This structure can reduce light loss in the light transmissive layer 130.

In another embodiment, referring to FIG. 6, the light exit surface of the light transmissive layer 130 may have a smaller area than the light incident surface thereof. This structure can reduce light emission from a side surface of the light transmissive layer 130. In this case, the light exit surface of the light transmissive layer 130 may be an upper surface of the light transmissive layer 130 facing away the active layer. The light incident surface of the light transmissive layer 130 may be a lower surface of the light transmissive layer 130 adjacent to the active layer. Here, an inclined surface may be formed on the side surface of the light transmissive layer 130.

Referring again to FIG. 5, the low light transmissive layer 150 may have a width in the horizontal direction (X-axis direction) perpendicular to the stacking direction of the semiconductor layers, in which the width in the horizontal direction is constant along a height of the low light transmissive layer 150 (stacking direction, height in the Z-axis direction). Alternatively, the low light transmissive layer 150 may have at least one point at which the width in the horizontal direction (X-axis direction) perpendicular to the stacking direction of the semiconductor layers varies. A width E′ from a side of the low light transmissive layer 150 to a side of the active layer of the light emitting device 120 may be greater than a width E from a side of the low light transmissive layer 150 to a side of the light transmissive layer 130. With this structure, the light emitting diode package can suppress light emission in the horizontal direction while reducing light that is not excited in a fluorescent material, thereby reducing chromatic aberration of the beam pattern IM in each region.

Furthermore, the width E from a side of the low light transmissive layer 150 to a side of the light transmissive layer 130 may be smaller than the width E′ from a side of the low light transmissive layer 150 to the active layer of the light emitting device 120. With this structure, the light emitting diode package can reduce lateral light of the light emitting device 120 while increasing light directed towards the light transmissive layer 130, thereby improving clarity of a projection image. Here, the width E from a side of the low light transmissive layer 150 to a side of the light transmissive layer 130 may be 50% to 80% of the width E′ from a side of the low light transmissive layer 150 to the active layer of the light emitting device 120. If the width difference is less than 50%, there is a problem of insufficient blocking of lateral light, and if the width difference therebetween is greater than 80%, the light emitting diode package can suffer from deterioration in light extraction efficiency due to reduction in light emission toward the light transmissive layer 130.

In another example, referring to FIG. 6, the light incident surface of the light transmissive layer 130 may have a different area than the light exit surface thereof. For example, the light exit surface may have a smaller area than the light incident surface. In addition, the area of the light exit surface of the light transmissive layer 130 may be smaller than the area of the active layer. The area of the light transmissive layer 130 may become narrower with increasing distance from the active layer.

In at least one region, the light transmissive layer 130 may have a thinner thickness in the stacking direction of the semiconductor layers in an outer peripheral region away from the center of the light emitting region of the light emitting device 120. The thickness of the light transmissive layer 130 in a region near the center of the light emitting device 120 may be constant. By maintaining the thickness of the light transmissive layer 130 in the region near the light emitting device 120 constant, it is possible to improve clarity while reducing deterioration in light extraction efficiency in the light transmissive layer 130. At least one region of the light transmissive layer 130 may have an inclination toward the center of the light emitting device 120. With this structure, the light emitting diode package partially reflects light directed outward back toward a central region of the light emitting device 120, thereby increasing the intensity of light in the central region while further improving clarity of the projection image.

Furthermore, in FIG. 6, the low light transmissive layer 150 may include a region in which the width in the horizontal direction (X-axis direction) perpendicular to the stacking direction of the semiconductor layers varies from the light transmissive layer 130 in the vertical direction (stacking direction of the semiconductor layers, Z-axis direction). For example, the low light transmissive layer 150 may include a region in which the width E in the horizontal direction (X-axis direction) perpendicular to the stacking direction of the semiconductor layers increases from the light transmissive layer 130 along the vertical direction (stacking direction of the semiconductor layers, Z-axis direction). In an upper region of the light transmissive layer 130, the width E′ of the low light transmissive layer 150 may be greater than the width E″ from a side of the active layer of the light emitting device 120 to a side of the low light transmissive layer 150. With this structure, the light emitting diode package can provide a narrow beam pattern IM by reflecting lateral light in the upper region of the light transmissive layer 130 from the center of the light emitting device 120.

Referring to FIG. 7, the cover region covered by the cover layer 140 on the upper surface of the light transmissive layer 130 may have a smaller area than the exposure region excluding the cover region. This structure can minimize light loss through the exposure region of the light transmissive layer 130. Furthermore, the exposure region may have a smaller area than the upper surface of the low light transmissive layer 150. With this structure, the light emitting diode package can suppress emission of lateral light through the side surface of the light emitting diode package 100, thereby reducing chromatic aberration. The area of the cover layer 140 may be larger than or equal to 5% and less than 20% of the area of the light transmissive layer 130. If the area of the cover layer 140 is larger than 20% of the area of the light transmissive layer 130, there can be a problem of deterioration in luminous efficacy, and if the area of the cover layer 140 is smaller than 5% of the area of the light transmissive layer 130, there can be a problem of reduced resolution of the beam pattern IM.

As the cover layer 140 partially covers the upper surface of the light transmissive layer 130, a boundary may be formed between the cover region and the exposure region. The boundary may refer to a line that separates the cover region and the exposure region in a plan view, and may be composed of various combinations of a straight line and a curved line.

For example, as shown in FIG. 7, the boundary between the cover region covered by the cover layer 140 and the exposure region excluding the cover region on the upper surface of the light transmissive layer 130 may include a stepped structure. In particular, the boundary may include at least one point at which the boundary bends from one end to the other end.

Referring to FIG. 7, the boundary may include a first boundary line L1 parallel to a first direction, a second boundary line L2 connected to the first boundary line L1 and forming a first angle Θ with the first boundary line L1, and a third boundary line L3 connected to the second boundary line L2 and parallel to the first direction.

The first direction is a direction parallel to a side surface of the light emitting diode package 100 and may be parallel to the x-axis direction in FIG. 7.

The first boundary line L1 may be a part of the boundary line extending parallel to the first direction from a side edge of the upper surface of the light transmissive layer 130 and may be formed to a predetermined length. With this structure, it is possible to determine the width of a third region N3 of the beam pattern IM in the first direction. The first boundary line L1 may be composed of a straight line. In addition, the first boundary line L1 may include a curved line in at least a section thereof. This structure can reduce cohesive stress at a corner of the boundary, thereby reducing cracking at the corner while improving structural stability.

The second boundary line L2 may be a part of the boundary line connected to the first boundary line L1 and forming a first angle Θ with the first boundary line L1. The second boundary line L2 may meet the first boundary line L1 at various points on the upper surface of the light transmissive layer 130. The first angle Θ formed by the second boundary line L2 with respect to the first boundary line L1 may be set in various ways. For example, the first angle Θ may be 15°, without being limited thereto.

Although FIG. 7 illustrates an example in which the second boundary line L2 has an upward slope with respect to the first boundary line L1, the second boundary line L2 may have a downward slope with respect to the first boundary line L1 in other embodiments.

The second boundary line L2 may be formed to a predetermined length. The second boundary line L2 may have a shorter length than the first boundary line L1. With this structure, it is possible to determine the width of a second region N2 of the beam pattern IM in the first direction. The second boundary line L2 may be composed of a straight line. Furthermore, the second boundary line L2 may include a curved line in at least a section thereof. This structure can reduce cohesive stress at a corner of the boundary, thereby reducing cracking at the corner while improving structural stability.

The third boundary line L3 may be a part of the boundary line connected to the second boundary line L2 and extending parallel to the first direction, and may extend to a side edge of the light transmissive layer 130. The boundary may start from the first boundary line L1 on a side of the light transmissive layer 130 and may extend to the other side of the light transmissive layer 130 through the third boundary line L3 via the second boundary line L2.

The third boundary line L3 may extend parallel to the first direction from one end of the second boundary line L2 to the side edge of the upper surface of the light transmissive layer 130, and may be formed to a predetermined length. With this structure, it is possible to determine the width of a first region N1 of the beam pattern IM in the first direction. The third boundary line L3 may be composed of a straight line. In addition, the third boundary line L3 may include a curved line in at least a section thereof. This structure can reduce cohesive stress at a corner of the boundary, thereby reducing cracking at the corner while improving structural stability. The second boundary line L2 may correspond to a bent section of the boundary and may be a slope zone SL having an inclination with respect to the first and third boundary lines L1, L3.

Due to the slope zone SL, a width T1 of the cover layer 140 in the first boundary line L1 may be different from a width T2 of the cover layer 140 in the third boundary line L3. For example, the width T1 of the cover layer 140 in the first boundary line L1 may be thinner than the width T2 of the cover layer 140 in the third boundary line L3.

Each of the widths T1, T2 of the cover layer 140 may refer to a length in the second direction (y-axis direction in FIG. 7) perpendicular to the first direction.

When the width of the light transmissive layer 130 is referred to as T, the width of the exposure region T in the first direction may also vary since the upper surface of the light transmissive layer 130 is partially covered by the cover layer 140. The exposure region is a light emission region from which light is emitted, and light emitted through the exposure region may be projected to form the beam pattern IM. The beam pattern IM may be formed along a light path in a shape of the exposure region inverted laterally and vertically.

Due to the boundary lines L1, L2, L3 forming edges of the exposure region, the beam pattern IM may also include at least one point at which the beam pattern bends from one end to the other end.

The beam pattern IM may include a third region N3 corresponding to the first boundary line L1 section, a second region N2 corresponding to the second boundary line L2 section, and a first region N1 corresponding to the third boundary line L3 section.

The third region N3 may be a region of the beam pattern IM in which light emitted from the exposure region corresponding to the first boundary line L1 section is projected. Since the exposure region corresponding to the first boundary line L1 section is a region having a relatively large width in the second direction, the exposure region may have a relatively higher irradiance than other regions. More particularly, the third region N3 may be a high irradiance region in the first direction.

The second region N2 may be a region of the beam pattern IM in which light emitted from the exposure region corresponding to the second boundary line L2 is projected. Since the exposure region corresponding to the second boundary line L2 section is a region having a variable width in the second direction, this exposure region may have a variable irradiance in the first direction. More particularly, the second region N2 may be a variable irradiance region in the first direction.

The first region N1 may be a region of the beam pattern IM in which light emitted from the exposure region corresponding to the third boundary line L3 section is projected. Since the exposure region corresponding to the third boundary line L3 section is a region having a relatively small width in the second direction, this exposure region may have a lower irradiance than other regions. More particularly, the first region N1 may be a low irradiance region in the first direction.

The second region (variable irradiance region) N2 and the third region (high irradiance region) N3 may have a light emission pattern that extends above an upper boundary of the first region (low irradiance region) N1 in the second direction perpendicular to the first direction.

The second region (variable irradiance region) N2 may have an inclined boundary at an edge thereof due to the effect of the slope zone SL, and the inclination of the inclined boundary may be equal to the first angle Θ. A cut-off line CL of FIG. 2 may be formed in the beam pattern IM by the first boundary line L1, the second boundary line L2, and the third boundary line L3.

As such, since the boundary has a bent point in at least a section thereof instead of being composed of a straight line, the beam pattern IM of light emitted through the exposure region may have an asymmetrical light emission pattern.

For example, as shown in FIG. 7, the beam pattern IM may have an asymmetrical light emission pattern with respect to an imaginary line (imaginary line extending in the y-axis direction) that passes through the center of the first direction (x-axis direction) and is perpendicular to the first direction.

With an asymmetrical exposure region formed by the cover layer 140 and allowing light emitted from the exposure region to have an asymmetrical light emission pattern, the light emitting diode package 100 can form an asymmetrical beam pattern IM having the cut-off line CL, as shown in FIG. 2, even if a component, such as a separate cut-off shield member, is omitted. Accordingly, the light emitting diode package 100 has an advantage of realizing a low beam headlamp with a simpler and more compact structure.

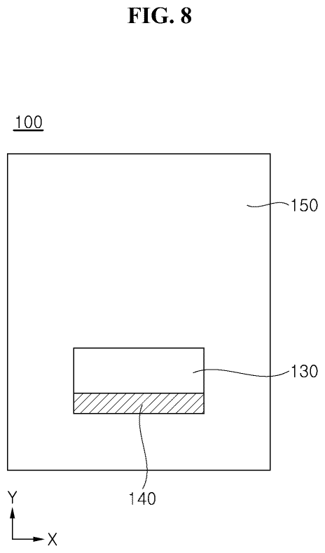

It should be understood that the boundary between the cover layer 140 and the light transmissive layer 130 is not limited to the stepped structure, as shown in FIG. 7. In some embodiments, on the upper surface of the light transmissive layer 130, the boundary between the cover region covered by the cover layer 140 and the exposure region excluding the cover region may be composed of a straight line or a curved line. For example, the shape of the boundary may be a simple straight line shape, as shown in FIG. 8, or may be modified in various ways depending on the beam pattern IM to be designed.

The light emitting diode package 100 may constitute various light emitting apparatuses 1000, 2000.

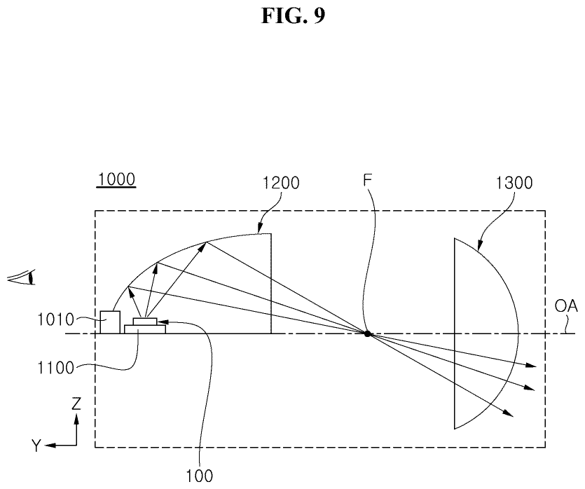

FIG. 9 shows a light emitting apparatus 1000 according to a first embodiment. The light emitting apparatus 1000 may include a light emitting diode package 100, a reflector 1200 on which light emitted from the light emitting diode package 100 is incident, and a lens 1300 that controls an optical path of light reflected from the reflector 1200.

The light emitting diode package 100 may be disposed on a base substrate 1100. The light emitting diode package 100 may be externally powered through an adapter 1010.

Referring to FIG. 9, the light emitting diode package 100 may be disposed on an upper surface of the base substrate 1100, which is disposed on a reference horizontal line OA. Here, the exposure region from which light is emitted may face upward perpendicular to the horizontal line OA.

On the horizontal line OA, the light emitting apparatus 1000 may have a focal point F on which light emitted from the light emitting apparatus 1000 converges. Light emitted from the light emitting diode package 100 may pass through the focal point F to form an upwardly or downwardly inverted beam pattern IM. With this structure, it is possible to make it easier to design the shape of the beam pattern IM.

The reflector 1200 is an optical member on which light emitted from the light emitting diode package 100 is incident and reflects the incident light, and may have various configurations. The reflector 1200 may include a reflector having an inner parabolic surface, and may reflect light incident on the parabolic surface. The reflector 1200 may be a region of an ellipse. The focal point F may be an outer focal point of an elliptical reflector 1200. The elliptical reflector 1200 can make it easier to design a focal region. The light emitting diode package 100 may be disposed at an inner focal point F of the reflector 1200 to project light toward the parabolic surface. At least a region of an inner surface of the reflector 1200 may be coated with a highly reflective material. The reflector 1200 may have a higher light reflectivity than the low light transmitter layers 150 or the cover layer 140. With this structure, the reflector can prevent light from being reintroduced into the light emitting diode package 100, thereby improving luminous efficacy.

The lens 1300 may control an optical path of light reflected from the reflector 1200 and may be formed of various shapes and materials. Light reflected from the reflector 1200 may be incident on the lens 1300 and emitted therefrom. Although FIG. 8 shows an example in which the lens 1300 is composed of a single lens, it should be understood that the lens 1300 may be composed of a plurality of lenses in other embodiments.

Light emitted through the lens 1300 may form a particular beam pattern IM. For example, the beam pattern IM may be a low beam pattern having the cut-off line CL, as shown in FIG. 2. In particular, a conventional light emitting apparatus requires a cut-off shield between the reflector 1200 and the lens 1300 with reference to the horizontal line OA, whereas the light emitting apparatus according to an embodiment may obviate a separate cut-off shield between the reflector 1200 and the lens 1300, thereby reducing design difficulty and the size of the light emitting apparatus.

Since the light emitting apparatus 1000 includes the light emitting diode package 100 capable of forming an asymmetric beam pattern IM, a low beam pattern, as shown in FIG. 2, can be realized with a simple structure even without a separate cut-off shield member to form the cut-off line CL.

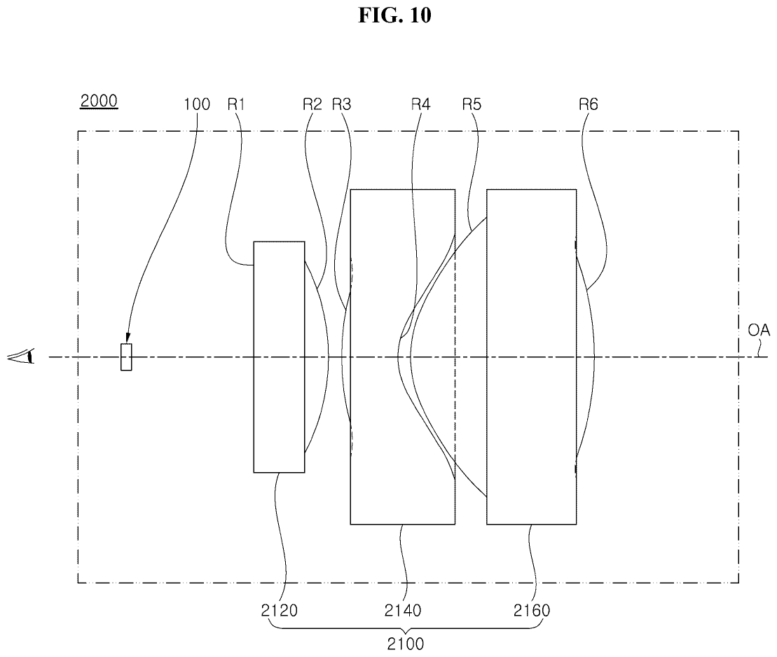

FIG. 10 shows a light emitting apparatus 2000 according to a second embodiment. The light emitting apparatus 2000 may include a light emitting diode package 100 and a lens module 2100 on which light emitted from the light emitting diode package 100 is incident.

Referring to FIG. 10, the light emitting diode package 100 may be disposed to emit light parallel to the reference horizontal line OA.

The lens module 2100 may include at least one lens 2120, 2140, 2160 as an optical member on which light emitted from the light emitting diode package 100 is incident.

The lens module 2100 may include a plurality of refractive surfaces R1 to R6 sequentially disposed in a traveling direction of the emitted light. The lens module 2100 may include at least four refractive surfaces R1 to R6, for example, five or six refractive surfaces, without being limited thereto.

The refractive surfaces R1 to R6 may be planar, concave, or convex.

For example, the lens module 2100 may include a first lens 2120, a second lens 2140, and a third lens 2160 sequentially disposed in the traveling direction of the emitted light.

Optical axes of the first lens 2120, the second lens 2140, and the third lens 2160 may be coincident with the reference horizontal line OA. The first lens 2120, the second lens 2140, and the third lens 2160 may be formed of the same material, or at least one of the first lens 2120, the second lens 2140, and the third lens 2160 may be formed of a different material from the other lenses 2120, 2140, 2160.

The first lens 2120, the second lens 2140, and the third lens 2160 may have the same coefficient of thermal expansion, or at least one of the first lens 2120, the second lens 2140, and the third lens 2160 may have a different coefficient of thermal expansion from the other lenses 2120, 2140, 2160.

In one example, the first lens 2120 disposed near the light emitting diode package 100 may have the lowest coefficient of thermal expansion. With this structure, the first lens 2120 can be prevented from expanding and changing focus due to heat generated from a light source, that is, the light emitting diode package 100. Further, at least one of the first lens 2120, the second lens 2140, and the third lens 2160 may have different thermal resistance from the other lenses 2120, 2140, 2160.

As another example, the first lens 2120 disposed near the light emitting diode package 100 may be formed of a material that has high thermal resistance. With this structure, it is possible to reduce damage to the first lens 2120 due to heat generated from the light emitting diode package 100.

To increase heat resistance, the first lens 2120 may further include additives. Alternatively, at least one of the first lens 2120, the second lens 2140, and the third lens 2160 may include additives. Still alternatively, at least two of the first lens 2120, the second lens 2140, and the third lens 2160 may include additives. The additives in the first lens 2120, the second lens 2140, or the third lens 2160 may be the same as or different from the additives in the other lenses 2120, 2140, 2160. With this structure, the lens module can improve heat resistance while reducing impact of transmittance in each region.

The first lens 2120, the second lens 2140, and the third lens 2160 may have the same index of refraction, or at least one of the first lens 2120, the second lens 2140, and the third lens 2160 may have a different index of refraction from the other lenses 2120, 2140, 2160. The light emitted from the light emitting diode package 100 may sequentially pass through the first lens 2120, the second lens 2140, and the third lens 2160 in sequence and then externally form the beam pattern IM.

The first lens 2120 may include a first refractive surface R1 on which light is incident and a second refractive surface R2 through which light exits. The first refractive surface R1 may have a smaller curvature than the second refractive surface R2. For example, the first refractive surface R1 may be a planar surface and the second refractive surface R2 may be a convex surface. The convex surface of the second refractive surface R2 may be convex in a traveling direction of light. With this structure, the second refractive surface R2 can refract light to reduce a beam angle of the light.

The second refractive surface R2 may be a convex, spherical surface (conic constant K=0). For example, the second refractive surface R2 may have a diameter of 13 mm to 16 mm and a radius of curvature of 16 mm to 16.6 mm.

The first lens 2120 is a lens disposed most adjacent to the light emitting diode package 100 and may be formed of a heat resistant material. For example, the first lens 2120 may be formed of a polycarbonate (PC) material, which has high heat resistance and a high heat deflection temperature. However, it should be understood that this material is provided only by way of example and the first lens 2120 may be formed of various materials in other embodiments.

The first lens 2120 may have a lower coefficient of thermal expansion than the second and third lenses 2140, 2160.

Since the first lens 2120 is formed of a heat resistant material and thus has a high heat deflection temperature, the first refractive surface R1 may be composed of a planar surface and the second refractive surface R2 may be composed of a spherical surface to facilitate molding, thereby securing ease of manufacturability through a simple structure.

The second lens 2140 is a lens disposed adjacent to the first lens 2120 and may include a third refractive surface R3 on which light is incident and a fourth refractive surface R4 through which light exits.

The third refractive surface R3 may be a surface facing the second refractive surface R2 and may be a convex surface on which light emitted from the second refractive surface R2 is incident. The third refractive surface R3 may be spaced apart from the second refractive surface R2. The separation distance may be less than the thickness of the first lens 2120. This structure allows the path of light to be adjusted.

The third refractive surface R3 may be a convex, aspherical surface. Here, the third refractive surface R3 may have a conic constant K of −1 or less, for example, −6.7. In an embodiment, the third refractive surface R3 may have a diameter of 15 mm to 17 mm and a radius of curvature of 12 mm to 12.8 mm. The diameter of the third refractive surface R3 may be greater than the diameter of the second refractive surface R2. Furthermore, on the reference horizontal line OA, the third refractive surface R3 may have a smaller radius of curvature than the second refractive surface R2. This structure allows the optical path of light emitted from the second refractive surface R2 to be adjusted. In addition, an outer curved region of the third refractive surface R3 with reference to the reference horizontal line OA may further include a concave region. The concave region may collect light emitted from the second refractive surface and traveling outwards to be directed inwards. With this structure, it is possible to increase the intensity of light in a central region of the lens module. Here, the third refractive surface R3 may have a smaller radius of curvature in the outer concave region thereof than on the reference horizontal line OA.

The fourth refractive surface R4 may be a light exit surface of the second lens 2140. The fourth refractive surface R4 may be a concave, aspherical surface. Here, the fourth refractive surface may have a greater conic constant than the third refractive surface. For example, the fourth refractive surface R4 may have a conic constant K of −2. In an embodiment, the fourth refractive surface R4 may have a diameter of 18 mm to 20 mm and a radius of curvature of 4 mm to 5.4 mm. The diameter of the fourth refractive surface R4 may be greater than the diameter of the second and third refractive surfaces R2, R3, and, on the reference horizon OA, the radius of curvature of the fourth refractive surface R4 may be smaller than the radius of curvature of the second and third refractive surfaces R2, R3.

As the fourth refractive surface R4 has a concave surface, an inwardly recessed depression may be formed on the second lens 2140. With this structure, it is possible to narrow a beam angle on the light exit surface of the second lens 2140.

The fourth refractive surface R4 may have different curvatures in different regions. In one example, the fourth refractive surface R4 may have an outwardly convex region. This region may have a smaller curvature than the curvature on the reference horizontal line OA. With this structure, the fourth refractive surface can inwardly narrow light emitted from the light exit surface of the second lens 2140.

The second lens 2140 may be formed of a different material from the first lens 2120 and thus may have a different index of refraction. The first lens 2120 may have a higher index of refraction than the second lens 2140. With this structure, the first lens can realize sufficient refraction of light with a thinner thickness than the second lens 2140.

Since the second lens 2140 is an aspherical lens, the second lens 2140 may be formed of a material that is easier to mold than the first lens 2120. The second lens 2140 may have a smaller index of refraction than the first lens 2120. With this structure, the second lens 2140 having a more complex shape than the first lens 2120 can be easily realized.

The third lens 2160 is a lens disposed adjacent to the second lens 2140 and may include a fifth refractive surface R5 on which light is incident and a sixth refractive surface R6 through which light exits.

The fifth refractive surface R5 may face the fourth refractive surface R4 and may be a convex surface on which light emitted from the fourth refractive surface R4 is incident. A region of the fifth refractive surface R5 may be located in a region within a depression formed by the fourth refractive surface R4 and may be spaced apart from the fourth refractive surface R4. More particularly, the fifth refractive surface R5 may have a region that overlaps with the fourth refractive surface R4 when viewed in a direction perpendicular to an optical axis.

This structure allows light emitted from the fourth refractive surface R4 to be efficiently incident on the fifth refractive surface R5. In addition, the fifth refractive surface also includes a region in which a separation distance between the fourth and fifth refractive surfaces R4 and R5 is closer than a separation distance therebetween on the reference horizontal line OA. With this structure, it is possible to adjust the beam pattern IM region in an outer peripheral region.

The fifth refractive surface R5 may be a convex, aspherical surface. Here, the fifth refractive surface R5 may have a conic constant K of −1 to 0. For example, the fifth refractive surface R5 may have a conic constant K of −0.6. In an embodiment, the fifth refractive surface R5 may have a diameter of 19 mm to 21 mm and a radius of curvature of 7 mm to 8.8 mm. The diameter of the fifth refractive surface R5 may be greater than the diameter of the second to fourth refractive surfaces R2, R3, R4. This structure allows light emitted from the fourth refractive surface R4 to be sufficiently incident on the third lens 2160, thereby preventing deterioration in luminous efficacy. On the reference horizontal line OA, the radius of curvature of the fifth refractive surface R5 may be smaller than the radius of curvature of the second and third refractive surfaces R2, R3. In addition, the radius of curvature of the fifth refractive surface R5 may be greater than the radius of curvature of the fourth refractive surface R4. This structure refracts light incident on the fifth refractive surface R5 in different directions to be directed toward a predesigned region. The fifth refractive surface R5 may also have a region in which the curvature gradually decreases from the center of the reference horizontal line OA. This structure allows light to spread over a larger area in an outer peripheral region of the fifth lens 2160, thereby widening the area of the beam pattern IM.

The sixth refractive surface R6 may be a light exit surface of the third lens 2160. The sixth refractive surface R6 may be a convex, aspherical surface. The sixth refractive surface R6 may have a conic constant K of −0.9. In an embodiment, the sixth refractive surface R6 may have a diameter of 18 mm to 20 mm and a radius of curvature of 20 mm to 20.6 mm. The diameter of the sixth refractive surface R6 may be greater than the diameters of the second and third refractive surfaces R2, R3, and smaller than the diameter of the fifth refractive surface R5. On the reference horizontal line OA, the radius of curvature of the sixth refractive surface R6 may be greater than the radius of the second to fifth refractive surfaces R2, R3, R4, R5.

The sixth refractive surface R6 may include a concave region outside the reference horizontal line OA. This structure allows light emitted from an outer peripheral region of the sixth refractive surface R6 to be collected in a certain region.

The third lens 2160 may be formed of a different material from the first or second lens 2120, 2140 and thus may have a different index of refraction.

Since the third lens 2160 is an aspherical lens, the third lens 2160 may be formed of a material that is easier to mold than the first lens 2120. The third lens 2160 may have a lower index of refraction than the second lens 2140.

A relationship between the indices of refraction of the first and third lenses 2120, 2140, 2160 may be varied. For example, the second lens 2140 may have the highest index of refraction. In another example, the second lens 2140 may have the lowest index of refraction. In still another example, the first lens 2120 may have the lowest index of refraction. The refractive indices of the first to third lenses 2120, 2140, 2160 may be varied in consideration of the optical path of emitted light.

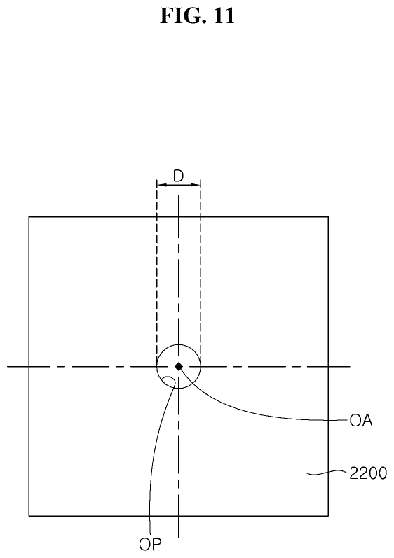

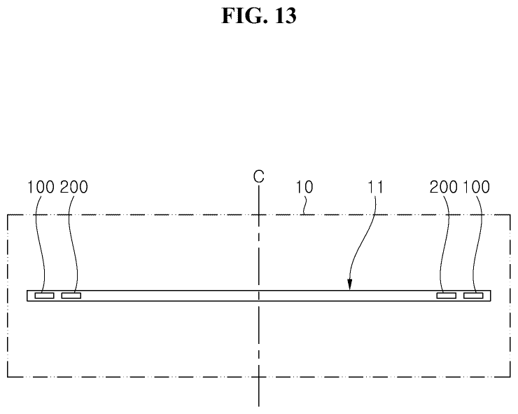

Referring to FIG. 11, the light emitting apparatus 2000 may further include an aperture 2200 including an aperture OP through which the light emitted from the lens module 2100 passes. The aperture 2200 may be disposed at a light exit side of the lens module 2100. The aperture OP may be an opening having a diameter D and the center of the aperture OP may coincide with the optical axis of the lens module 2100. The diameter D of the aperture OP may be set in various ways. For example, the aperture OP may have a diameter D of 5 mm to 15 mm. In an embodiment, the aperture OP may have a diameter D of 10 mm. Light having passed through the aperture OP may form a beam pattern IM in which the exposure region of the light transmissive layer 130 is inverted vertically and laterally. The aperture 2200 can protect the lens module 2100 from an external environment. The aperture 2200 may have a rectangular opening with a diameter (D) in a longitudinal direction thereof. The aperture 2200 may have a rectangular shape, as the light emitting diode packages 100, 200 shown in FIG. 13. With this structure, the light emitting apparatus can improve design aesthetics.

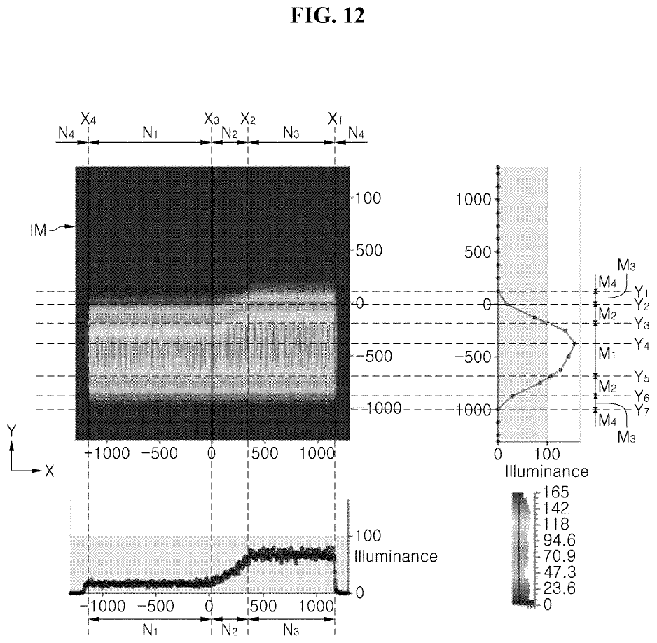

FIG. 12 is a graph depicting a light emission pattern and irradiance in each region formed in the light emitting apparatuses 1000, 2000 including the light emitting diode package 100 according to an embodiment of the present invention. The light emission pattern may be a beam pattern IM of light emitted from the light emitting diode package 100.

Each of the light emitting apparatuses 1000, 2000 may be a low beam headlamp of a vehicle, and the beam pattern IM may be a low beam pattern including a cut-off line CL.

One region of the beam pattern IM may be divided into a plurality of regions N1, N2, N3 having different irradiances in a first direction. Similarly, the beam pattern IM may be divided into a plurality of regions M1, M2, M3, M4 having different irradiances in a second direction perpendicular to the first direction. Referring to FIG. 12, the first direction may refer to a direction parallel to the x-axis and the second direction may refer to a direction parallel to the y-axis.

Specifically, in the first direction, the beam pattern IM including the cut-off line CL may sequentially include a first region (low irradiance region) N1, a second region (variable irradiance region) N2, and a third region (high irradiance region) N3. The first region (low light region) N1 may be a light emitting region corresponding to the third boundary line L3 shown in FIG. 7.

The low irradiance region N1 may have an irradiance of 5% or more relative to a light emission peak. The low irradiance region N1 may correspond to coordinates from X4 to X3 in the first direction. The low irradiance region N1 may be a light emitting region corresponding to the third boundary line L3 and may have a relatively low irradiance due to a region shielded by the cover layer 140.

The variable irradiance region N2 may have an irradiance of 30% or more relative to the light emission peak and the irradiance of the variable irradiance region may vary in the first direction. The variable irradiance region N2 may correspond to coordinates from X3 to X2 in the first direction. Here, X3 may be set to 0 as an x-axis direction reference. The x-axis direction reference may not coincide with the center of the light emitting diode package 100. The variable irradiance region N2 may correspond to the slope zone SL formed by the cover layer 140 shown in FIG. 7. The variable irradiance region N2 may have a variable irradiance gradually increasing with increasing distance from the low irradiance region N1. In the variable irradiance region N2, a boundary inclination of the beam pattern IM may be similar to an angle Θ of the slope zone SL and may have an angular difference, in particular within 5°. The cut-off line CL of the light emitting apparatus 1000, 2000 can be realized through the slope zone SL.

The high irradiance region N3 may have an irradiance of 60% or more relative to the light emission peak. The high irradiance region N3 may correspond to coordinates from X2 to X1 in the first direction. The high irradiance region N3 may be a third region formed by the first boundary line L1 of the light emitting diode package 100 shown in FIG. 7.

With this structure, the light emitting apparatus can relatively increase the irradiance of a region located far from a driver's seat and not interfering with a driver's vision of a vehicle traveling in an opposite direction while realizing an effective dipped beam.

The beam pattern IM may have an asymmetrically shape in the first direction and the variable irradiance region N2 may be a region in which an inclined cut-off line CL of the beam pattern IM appears.

Next, in the second direction, the beam pattern IM may sequentially include a third region M3, a second region M2, a first region M1, another second region M2, and another third region M3. The fourth region M4 outside the third region M3 may be a non-emissive region with zero irradiance. In FIG. 12, a reference point of the beam pattern IM is a point where the x-axis coordinate value and the y-axis coordinate value are both zero (0, 0), and may correspond to a point where the first boundary line L1 and the second boundary line L2 of the light emitting diode package 100 meet. This point may be present in a region biased to a side from the center of the light emitting diode package 100. With this structure, the light emitting apparatus can realize a dipped beam.

The first region M1 may include a light emission peak point Y4 where the light emission peak appears in the second direction, and may have an irradiance of 60% or more relative to the light emission peak. The first region M1 may correspond to coordinates from Y3 to Y5 in the second direction.

The second region M2 may be adjacent to the first region M1 and may have an irradiance of 30% to 60% relative to the light emission peak. The second region M2 may correspond to coordinates from Y2 to Y3 and Y5 to Y6 in the second direction.

The third region M3 may be adjacent to the second region M2 and may have an irradiance of 30% or less relative to the light emission peak. The third region M3 may correspond to coordinates from Y1 to Y2 and Y6 to Y7 in the second direction. The third region M3 (Y1 to Y2) may have an asymmetrical shape in the first direction due to the inclined cut-off line CL of the variable irradiance region N2.

The irradiance of the beam pattern IM in the second direction may have an asymmetrical shape with respect to a light emission peak Y4, such that an upper side Y1 to Y4 of the light emission peak Y4 exhibit a more gradual change in irradiance than a lower side Y4 to Y7 thereof. With this structure, the light emitting apparatus can realize a wider and smoother light emission pattern in a low beam region located below the reference point of the beam pattern IM.

FIG. 13 is a conceptual diagram of an automotive headlamp 11 including the light emitting diode package 100 according to an embodiment of the present invention, in which the light emitting diode package 100 may be symmetrically disposed with respect to a widthwise center C of a vehicle 10. At least one light emitting diode package 100 may be provided for a right headlamp of the vehicle 10 and at least one other light emitting diode package 100 may be provided for a left headlamp of the vehicle 10. The right and left headlamps may be realized by the light emitting apparatus 1000, 2000 of FIG. 9 or FIG. 10, each of which includes the light emitting diode package 100, and may be low beam emitting headlamps.

The automotive headlamp 11 may further include light emitting diode packages 200 for high beam emitting headlamps. At least one light emitting diode package 200 may be provided for a right headlamp of the vehicle 10, and at least one other light emitting diode package 200 may be provided for a left headlamp of the vehicle 10. The light emitting diode packages 200 may emit a high beam, in which the beam pattern IM does not include a cut-off line CL unlike the low beam and is configured to emit light forward rather than downward. Accordingly, the cover layer 140 may be omitted from the light emitting diode package 200. Furthermore, the light emitting apparatus including the light emitting diode package 200 may include at least one lens or at least one refractive surface for controlling the path of light emitted from the light emitting diode package 200, as a device constituting a high beam emitting headlamp.

In the headlamp 11 shown in FIG. 13, the light emitting diode packages 100, 200 are not secured at a certain location, and the light emitting diode package 100 for the low beam and the light emitting diode package 200 for the high beam may be interchangeably located.

Since the light emitting diode package 100 and the light emitting apparatuses 1000, 2000 according to embodiments of the present invention can form a low beam pattern with a simpler structure, a more compact structure and arrangement can be achieved in construction of the automotive headlamp 11.

Embodiments of the present invention may provide a light emitting diode package and a light emitting apparatus including the same having a simple structure and can form a beam pattern of a desired shape with a compact size.

Embodiments of the present invention may provide a light emitting diode package and a light emitting apparatus including the same that reduces chromatic aberration.

Embodiments of the present invention may provide a light emitting diode package and a light emitting apparatus including the same that improves the sharpness of a projection image.

Embodiments of the present invention may provide a light emitting diode package a light emitting apparatus including the same that improves reliability and.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting apparatus comprising:
a light emitting device;
a light transmissive layer disposed on the light emitting device; and
a cover layer disposed on the light transmissive layer and partially covering an upper surface of the light transmissive layer,
wherein the cover layer has a lower light transmittance than the light transmissive layer, and
wherein the upper surface of the light transmissive layer has a cover region covered by the cover layer, an exposure region exposed from the cover region, and a boundary between the cover region and the exposure region, the boundary including a stepped structure.

2. The light emitting apparatus according to claim 1, further comprising a low light transmissive layer surrounding the light transmissive layer,
wherein the low light transmissive layer has a lower light transmittance than the light transmissive layer.

3. The light emitting apparatus according to claim 2, wherein the cover layer has a lower light transmittance than the low light transmissive layer.

4. The light emitting apparatus according to claim 1, wherein the boundary includes a first boundary line parallel to a first direction, a second boundary line connected to the first boundary line and forming a first angle with the first boundary line, and a third boundary line connected to the second boundary line and parallel to the first direction.

5. The light emitting apparatus according to claim 4, wherein the second boundary line includes a slope zone having an inclination with respect to the first and third boundary lines.

6. The light emitting apparatus according to claim 4, wherein the cover region has a smaller area than the exposure region.

7. The light emitting apparatus according to claim 6, wherein a beam pattern of light emitted through the exposure region includes:
a high irradiance region corresponding to the first boundary line and having a relatively high irradiance;
a variable irradiance region corresponding to the second boundary line and having a variable irradiance;
and a low irradiance region corresponding to the third boundary line and having a relatively low irradiance.

8. The light emitting apparatus according to claim 7, wherein the beam pattern of the light emitted through the exposure region has an asymmetrical light emission pattern.

9. The light emitting apparatus according to claim 7, wherein the variable irradiance region and the high irradiance region have a light emission pattern extending above an upper boundary of the low irradiance region in a second direction perpendicular to the first direction.

10. A light emitting apparatus comprising:
a light emitting diode package including:
a light emitting device;
a light transmissive layer disposed on the light emitting device; and
a cover layer disposed on the light transmissive layer and partially covering an upper surface of the light transmissive layer;
a reflector on which light emitted from the light emitting diode package is configured to be incident; and
a lens configured to control an optical path of light reflected from the reflector,
wherein the cover layer has a lower light transmittance than the light transmissive layer, and
wherein the upper surface of the light transmissive layer has a cover region covered by the cover layer, an exposure region exposed from the cover region, and a boundary between the cover region and the exposure region, the boundary including a stepped structure.

11. The light emitting apparatus according to claim 10, further comprising a lens module on which light emitted from the light emitting diode package is incident.

12. The light emitting apparatus according to claim 11, wherein the lens module includes a plurality of refractive surfaces sequentially disposed in a traveling direction of the emitted light.

13. The light emitting apparatus according to claim 11, wherein the lens module includes a first lens, a second lens, and a third lens sequentially disposed in a traveling direction of the emitted light.

14. The light emitting apparatus according to claim 13, wherein:
the first lens includes a first refractive surface on which light is incident and a second refractive surface through which light exits;
the second lens includes a third refractive surface on which light is incident and a fourth refractive surface through which light exits; and
the third lens includes a fifth refractive surface on which light is incident and a sixth refractive surface through which light exits.

15. The light emitting apparatus according to claim 14, wherein:
the first refractive surface includes a planar surface;
the second refractive surface, the third refractive surface, the fifth refractive surface, and the sixth refractive surface include convex surfaces; and
the fourth refractive surface includes a concave surface.

16. The light emitting apparatus according to claim 14, wherein the first refractive surface includes a planar surface and the second refractive surface includes a spherical surface.

17. The light emitting apparatus according to claim 14, wherein the first lens has a lower coefficient of thermal expansion than the second lens and the third lens.

18. The light emitting apparatus according to claim 15, wherein the fifth refractive surface is located within at least one region of a depression formed by the fourth refractive surface.

19. The light emitting apparatus according to claim 13, wherein the first lens, the second lens, and the third lens have different indices of refraction.

20. A light emitting diode package including:
a light emitting device;
a light transmissive layer disposed on the light emitting device;
a cover layer disposed on the light transmissive layer and partially covering an upper surface of the light transmissive layer;
a lens module disposed on the light emitting diode and configured to control an optical axis; and
an aperture having an opening on a light exit side of the lens module,
wherein the cover layer has a lower light transmittance than the light transmissive layer,
wherein the upper surface of the light transmissive layer has a cover region covered by the cover layer, an exposure region exposed from the cover region, and a boundary between the cover region and the exposure region, the boundary including a stepped structure, and
wherein the opening of aperture is coincident with an optical axis of the lens module.
